(19) United States
(12) Patent Application Publication
(10) Pub. No.: US 2024/0379927 A1
(43) Pub. Date: Nov. 14, 2024

(54) LIGHT-EMITTING MODULE AND DISPLAY APPARATUS

(71) Applicant: QUANZHOU SANAN SEMICONDUCTOR TECHNOLOGY CO., LTD., Quanzhou (CN)

(72) Inventors: Chongde HONG, Quanzhou (CN); Junpeng SHI, Xiamen (CN); Zhen-duan LIN, Xiamen (CN); Yaxin QIU, Quanzhou (CN); Zhiyang ZENG, Quanzhou (CN); Jianchao CHENG, Quanzhou (CN); Qinghe CHEN, Quanzhou (CN); Chen-ke HSU, Xiamen (CN)

(21) Appl. No.: 18/780,857

(22) Filed: Jul. 23, 2024

Related U.S. Application Data
(63) Continuation of application No. PCT/CN2022/073810, filed on Jan. 25, 2022.

(51) Int. Cl. H01L 33/62; H01L 25/075; H01L 25/16; H01L 33/04; H01L 33/54

(52) U.S. Cl. CPC H01L 33/62; H01L 25/0753; H01L 25/167; H01L 33/04; H01L 33/54

(57) ABSTRACT

A display apparatus includes a thin-film transistor (TFT) substrate and a light-emitting module arranged on the TFT substrate. The light-emitting module includes multiple light-emitting elements, the light-emitting elements include a first light-emitting element emitting a first wavelength, a second light-emitting element emitting a second wavelength, and a third light-emitting element emitting a third wavelength. A voltage of each light-emitting element is greater than or equal to 3 volts (V) when a rated current is 1 microampere (μA).

### CROSS-REFERENCE TO RELATED APPLICATION

This application is a continuation of International Application No. PCT/CN2022/073810, filed on Jan. 25, 2022. The entire contents of the above-mentioned application are incorporated herein by reference.

### TECHNICAL FIELD

The disclosure relates to the technical field of semiconductors, and more particularly to a light-emitting module and a display apparatus.

### BACKGROUND

Light-emitting diodes (LEDs) are widely used in display apparatuses, vehicle lighting, general lighting and other fields due to their high reliability, long service life and low power consumption. For example, the LEDs can be used as backlight sources for various display apparatuses. In order to effectively mechanically protect the LEDs, light-emitting modules are often encapsulated and formed, which can enhance heat dissipation, improve luminous efficacy, and optimize light beam distribution. However, the reliability of the light-emitting module obtained by the existing method is poor, and how to obtain a high-reliability light-emitting module is still a difficult problem.

### SUMMARY

According to an embodiment disclosed in the disclosure, a display apparatus may include a thin-film transistor (TFT) substrate and a light-emitting module arranged on the TFT substrate. The light-emitting module includes multiple light-emitting elements. The light-emitting elements include a first light-emitting element emitting a first wavelength, a second light-emitting element emitting a second wavelength, and a third light-emitting element emitting a third wavelength. A voltage of each light-emitting element is greater than or equal to 3 volts (V) when a rated current is 1 microampere (μA).

According to another embodiment disclosed in the disclosure, the light-emitting module may include multiple groups of light-emitting elements, a wiring layer, and a conductive pad. The multiple groups of light-emitting elements are arranged in a centrosymmetric manner, each group includes multiple light-emitting elements arranged at intervals with different wavelength ranges. The wiring layer is arranged in the centrosymmetric manner, formed on the multiple groups of light-emitting elements and configured to electrically connect to the light-emitting elements. The conductive pad is arranged in the centrosymmetric manner, formed on a side of the wiring layer facing away from the light-emitting element and electrically connected to the wiring layer.

According to still another embodiment disclosed in the disclosure, the light-emitting module may include multiple groups of light-emitting elements, a wiring layer, and a conductive pad. The multiple groups of light-emitting elements, the wiring layer and the conductive pad are arranged in a centrosymmetric manner. Each group of light-emitting elements constitutes a pixel unit and includes multiple light-emitting elements arranged at intervals with different wavelength ranges. The wiring layer is arranged in the centrosymmetric manner, formed on the multiple groups of light-emitting elements and configured to electrically connect to the light-emitting elements. The conductive pad is arranged in the centrosymmetric manner, formed on a side of the wiring layer facing away from the light-emitting elements and electrically connected to the wiring layer. The light-emitting module can be overlapped with a layout of the light-emitting module before being rotated by 90 degrees in any direction.

### BRIEF DESCRIPTION OF DRAWINGS

In order to explain technical solutions of embodiments of the disclosure more clearly, the following drawings will be briefly introduced. It should be understood that the following drawings only illustrate some embodiments of the disclosure and are therefore not to be construed as limiting the scope. For those skilled in the art, other related drawings can be obtained according to these drawings without creative work.

FIG. 1 illustrates a plan view of a light-emitting module illustrated in an embodiment 1 of the disclosure.

FIG. 2 illustrates a sectional view taken along a line A-A′ in FIG. 1.

FIG. 3 illustrates another sectional view taken along the line A-A′ in FIG. 1.

FIG. 4 illustrates still another sectional view taken along the line A-A′ in FIG. 1.

FIG. 5 illustrates a plan view of a light-emitting module illustrated in an embodiment 2 of the disclosure.

FIG. 6 illustrates a plan view of a light-emitting module illustrated in an embodiment 3 of the disclosure.

FIG. 7 illustrates a plan view of a first wiring layer illustrated in the embodiment 3 of the disclosure.

FIG. 8 illustrates a plan view of a through-hole layer illustrated in the embodiment 3 of the disclosure.

FIG. 9 illustrates a plan view of a second wiring layer illustrated in the embodiment 3 of the disclosure.

FIG. 10 illustrates a plan view of a light-emitting module illustrated in an embodiment 4 of the disclosure.

FIG. 11 illustrates a plan view of a group of light-emitting elements illustrated in the embodiment 4 of the disclosure.

FIG. 12 illustrates a plan view of a light-emitting module illustrated in the embodiment 4 of the disclosure.

FIG. 13 illustrates a plan view of a group of light-emitting elements illustrated in the embodiment 4 of the disclosure.

FIG. 14 illustrates a plan view of a display apparatus illustrated in an embodiment 5 of the disclosure.

FIG. 15 illustrates a circuit diagram of a TFT driving circuit.

FIG. 16 illustrates electrical characteristics of the TFT driving circuit.

FIG. 17 illustrates a plan view of a light-emitting module illustrated in the embodiment 5 of the disclosure.

FIG. 18 illustrates a sectional view taken along a line B-B′ in FIG. 17.

FIG. 19 illustrates a schematic sectional view of a light-emitting element illustrated in the embodiment 5 of the disclosure.

FIG. 20 illustrates a schematic sectional view of another light-emitting element illustrated in the embodiment 5 of the disclosure.

### DESCRIPTION OF REFERENCE SIGNS

100 transparent layer; 1001 first transparent layer; 1002 second transparent layer; 200 light-emitting element; 201 first light-emitting element; 202 second light-emitting element; 203 third light-emitting element; 210 filling layer; 300 wiring layer; 301 first sub-wiring; 302 second sub-wiring; 303 third sub-wiring; 304 fourth sub-wiring; 305 fifth sub-wiring; 306 sixth sub-wiring; 307 seventh sub-wiring; 308 interconnect sub-wiring; 310 first layer; 320 second layer; 400 insulation layer; 500 conductive pad; 501 first sub-pad; 502 second sub-pad; 503 third sub-pad; 504 fourth sub-pad; 505 fifth sub-pad; 5001 common sub-pad; 5002 first independent sub-pad; 5003 second independent sub-pad; 5004 third independent sub-pad; 510 conductive layer; 520 adhesive layer; 530 protective layer; 540 eutectic layer; 600 encapsulation layer; 700 seed layer; 10000 display apparatus; 1000 light-emitting module; 11000 TFT substrate; 2011 first light-emitting diode; 2012 second light-emitting diode; 2021 third light-emitting diode; 2022 fourth light-emitting diode; 2031 fifth light-emitting diode; 2032 sixth light-emitting diode; 3005 first connection part; 3006 second connection part; 3007 third connection part; 20 semiconductor stack; 21 first semiconductor layer; 22 active layer; 23 second semiconductor layer; 24 connection electrode; 25 first electrode; 26 second electrode; 27 insulation protective layer; 35 tunneling junction.

### DETAILED DESCRIPTION OF EMBODIMENTS

The following describes the implementation of the disclosure through specific embodiments, and those skilled in the art can easily understand other advantages and effects of the disclosure from the contents disclosed in this specification. The disclosure can also be implemented or operated through different specific embodiments, and various details in the disclosure can be modified or changed based on different viewpoints and applications without departing from the spirit of the disclosure.

In the description of the disclosure, it should be noted that an azimuth or positional relationship indicated by terms “upper” and “lower” is based on the azimuth or positional relationship illustrated in the attached drawings, or an azimuth or positional relationship that a product of the disclosure is usually put in use, only for the convenience of describing the disclosure and simplifying the description, and does not indicate or imply that an apparatus or an element referred to must have a specific orientation, be constructed and operated in a specific orientation, so it cannot be understood as a limitation of the disclosure. In addition, terms “first” and “second” are only used to distinguish descriptions, and cannot be understood as indicating or implying relative importance.

### Embodiment 1

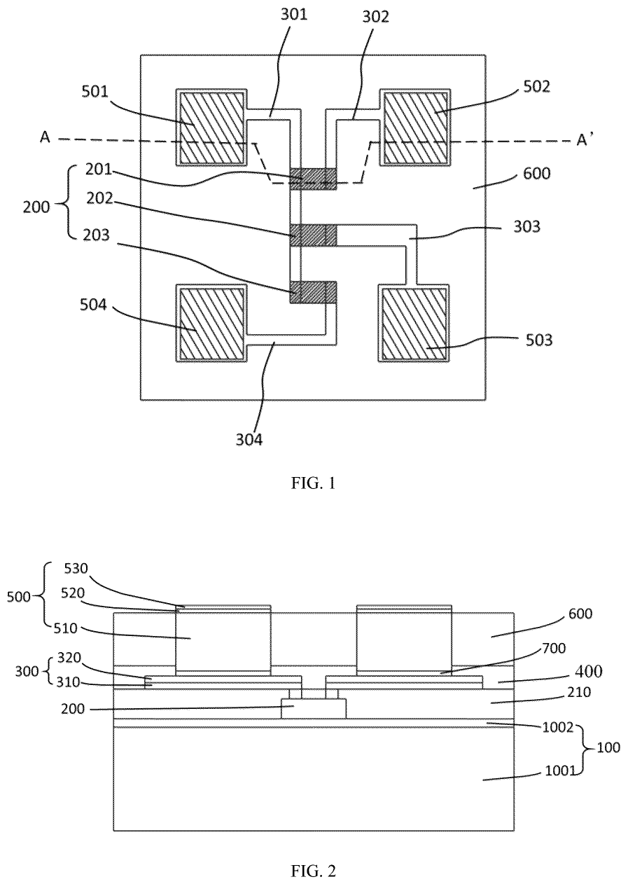

FIG. 1 illustrates a schematic plan view of a light-emitting module according to the embodiment 1 of the disclosure, and FIG. 2 illustrates a schematic sectional view taken along a cutting line A-A′ in FIG. 1.

Referring to FIGS. 1 and 2, the light-emitting module includes multiple light-emitting elements 200 arranged at intervals with different wavelength ranges, and a gap between adjacent light-emitting elements 200 is filled with a filling layer 210 to electrically isolate the adjacent light-emitting elements 200. A wiring layer 300 is formed on the multiple light-emitting elements 200 and is configured to electrically connect to the light-emitting elements 200. A conductive pad 500 is formed on a side of the wiring layer 300 facing away from the light-emitting elements 200, and is electrically connected to the light-emitting elements 200 through the wiring layer 300.

In an embodiment, the light-emitting element 200 mainly refers to a micron-sized light-emitting diode, and its width and length are in a range of 2-5 micrometers (μm), 5-10 μm, 10-20 μm, 20-50 μm, or 50-100 μm, and its thickness is in a range of 2-15 μm, specifically, 5-10 μm. In this embodiment, the light-emitting module includes a first light-emitting element 201, a second light-emitting element 202 and a third light-emitting element 203.

Specifically, each light-emitting element 200 includes a semiconductor stack. The semiconductor stack may include a first semiconductor layer and a second semiconductor layer sequentially arranged in that order, and an active layer arranged between them. The first semiconductor layer is an N-type semiconductor layer, the second semiconductor layer is a P-type semiconductor layer, and the active layer is a multi-quantum well (MQW) layer that can provide red light, green light or blue light radiation. The N-type semiconductor layer, the MQW layer and the P-type semiconductor layer are only basic constituent units of the light-emitting element 200, and on this basis, the light-emitting element 200 may also include other functional structural layers that have an optimization effect on the performance of the light-emitting element 200.

The first light-emitting element 201, the second light-emitting element 202 and the third light-emitting element 203 respectively radiate light in different wavelength ranges, for example, the first light-emitting element 201 radiates blue light, the second light-emitting element 202 radiates green light, and the third light-emitting element 203 radiates red light. In an embodiment, different light-emitting elements 200 may have different semiconductor stacks, so as to directly radiate light in different wavelength ranges, and the specific material of the semiconductor stacks is selected according to the wavelength of the radiated light, including but not limited to aluminum gallium arsenide (AlGaAs), gallium arsenide phosphide (GaAsP), aluminum gallium indium phosphide (AlGaInP), gallium nitride (GaN), indium gallium nitride (InGaN), zinc selenide (ZnSe), or gallium phosphide (GaP). In another embodiment, different light-emitting elements 200 may have the same semiconductor stacks. For example, the semiconductor stacks in the first light-emitting element 201, the second light-emitting element 202 and the third light-emitting element 203 all radiate blue light, and a wavelength conversion layer is arranged on a light-emitting surface of the second light-emitting element 202 to convert the radiated blue light into green light, and a wavelength conversion layer is arranged on a light-emitting surface of the third light-emitting element 203 to convert the radiated blue light into red light.

Each light-emitting element 200 further includes a first electrode and a second electrode. The semiconductor stack has a mesa exposing the first semiconductor layer, the first electrode is formed on the mesa and electrically connected to the first semiconductor layer, and the second electrode is formed on the second semiconductor layer and electrically connected to the second semiconductor layer.

In an embodiment, a thickness difference between the light-emitting elements 200 is less than or equal to 5 μm, which can effectively improve the transfer yield of the light-emitting module transferred to a transparent layer 100 described in the following, so as to improve the light-emitting effect of the light-emitting module.

In an embodiment, referring to FIGS. 1 and 2, the light-emitting module further includes the transparent layer 100, and the light-emitting elements 200 are arranged on the transparent layer 100, and a surface of the transparent layer 100 facing away from the light-emitting elements 200 is the light-emitting surface of the light-emitting module, that is, all the light emitted by the light-emitting elements 200 is emitted to the outside through the transparent layer 100. The transparent layer 100 has a light transmittance of more than 60% in a visible light range.

In an embodiment, referring to FIG. 2, the transparent layer 100 includes a first transparent layer 1001 and a second transparent layer 1002, and the second transparent layer 1002 is located between the first transparent layer 1001 and the light-emitting element 200.

The first transparent layer 1001 can be selected from inorganic light-transmitting materials such as glass, transparent ceramics and sapphire. In an embodiment, the light-emitting module needs to have a certain thickness to be used by the client, so a thickness of the first transparent layer 1001 is greater than 10 μm, specifically, 30-50 μm, 50-100 μm, or 100-300 μm.

The second transparent layer 1002 is located between the first transparent layer 1001 and the light-emitting elements 200, so that the light-emitting elements 200 can be adhered to the first transparent layer 1001 through the second transparent layer 1002. The second transparent layer 1002 can completely cover an entire surface of the first transparent layer 1001, but it is not limited to this, and the second transparent layer 1002 can also be located just below the light-emitting elements 200, so that the light-emitting element 200 can adhere to the transparent layer 1001 through the second transparent layer 1002.

Different light-emitting elements 200 usually have different thicknesses. By arranging the second transparent layer 1002 between the first transparent layer 1001 and the light-emitting elements 200, a height difference of the light-emitting surfaces of the light-emitting elements 200 is reduced, so that the light emitted from the sides of the light-emitting elements 200 is absorbed by the filling layer 210 described below as much as possible, and the contrast of the light-emitting module can be improved. A thickness of the second transparent layer 1002 is 1-15 μm or 3-10 μm. If the thickness of the second transparent layer 1002 is greater than 15 μm, the alignment accuracy of the light-emitting element 200 may be affected.

As an alternative embodiment, the first transparent layer 1001 can also be selected from thermosetting organic materials with low cost, such as epoxy resin, silica gel, polyimide, etc., due to the high cost of inorganic light-transmitting materials such as sapphire and the complicated preparation process. In an embodiment, the first transparent layer 1001 can be a component formed by dispersing nanoparticles such as zirconium dioxide, silicon oxide, aluminum oxide and boron nitride in organic light-transmitting materials such as epoxy resin, silica gel and polyimide. The nanoparticles such as zirconium dioxide, silicon oxide, aluminum oxide and boron nitride can improve the strength of the first transparent layer 1001. In addition, the contrast of the light-emitting module can be adjusted by adjusting the content of nanoparticles such as zirconium dioxide, silicon oxide, aluminum oxide and boron nitride. In an embodiment, when the first transparent layer 1001 is a thermosetting organic material, the second transparent layer 1002 can be ignored.

In an embodiment, referring to FIGS. 1 and 2, the light-emitting module further includes the filling layer 210, the filling layer 210 is filled between adjacent light-emitting elements 200 or around side walls of the light-emitting elements 200 to prevent color mixing or light interference between adjacent light-emitting elements 200, so as to improve the contrast of the light-emitting module. The filling layer 210 is provided as a black glue layer that absorbs light.

In a specific embodiment, the thickness range of the light-emitting elements 200 is in a range of 2-15 μm, and a spacing between adjacent light-emitting elements 200 is less than 50 μm. Therefore, a material with good fluidity is used for curing when forming the filling layer 210. In a specific embodiment, a particle size of a black filling component filled in the filler layer 210 is not more than 1/10 of the thickness of the light-emitting element 200, which can avoid the problem that the coating effect of the filler layer 210 on the light-emitting element 200 is poor due to the excessively large particle size of the black filling component, and further affect the contrast of the light-emitting module. The filler layer 210 can be a component formed by dispersing the black filling component with a particle size of not more than 1 μm in transparent or translucent materials such as silica gel, epoxy resin, polyimide, low-temperature glass, polysiloxane and polysilazane, and the black filler component in the filler layer 210 include but are not limited to carbon black, titanium nitride, iron oxide, ferroferric oxide and iron powder. The particle size range of the black filling component is specifically 10-100 nm, 100-200 nm, 200˜300 nm, or 300 nm˜500 nm. The filling layer 210 may also use a black dye.

The filling layer 210 covers at least 50% of the side wall of each light-emitting element 200 close to the light-emitting surface, and specifically covers all the side wall of each light-emitting element 200, so as to prevent color mixing or light interference between adjacent light-emitting elements 200 and improve the contrast of the light-emitting module. As an alternative embodiment, the thickness of the filling layer 210 may be greater than that of the light-emitting element 200, and light interference caused by light leakage at a bottom of the light-emitting element 200 can be prevented. The thickness of the filling layer 210 is specifically less than 15 μm.

In an embodiment, referring to FIGS. 1 and 2, the wiring layer 300 is formed on multiple light-emitting elements 200 and is configured to electrically connect to the light-emitting elements 200. The wiring layer 300 includes several wires, and a periphery of the wiring layer is filled with an insulation layer 400 to electrically isolate adjacent wires.

The wiring layer 300 includes a first sub-wiring 301, a second sub-wiring 302, a third sub-wiring 303 and a fourth sub-wiring 304. The first sub-wiring 301 serves as a common wiring, and first electrodes in the first light-emitting element 201, the second light-emitting element 202 and the third light-emitting element 203 are connected to the first sub-wiring 301. A second electrode in the first light-emitting element 201 is connected to the second sub-wiring 302. A second electrode in the second light-emitting element 202 is connected to the third sub-wiring 303. A second electrode in the third light-emitting element 203 is connected to the fourth sub-wiring 304. The wiring layer 300 may be formed together on the filling layer 210.

Alternatively, the first sub-wiring 301 serves as the common wiring, and the second electrodes in the first light-emitting element 201, the second light-emitting element 202 and the third light-emitting element 203 are connected to the first sub-wiring 301. The first electrode in the first light-emitting element 201 is connected to the second sub-wiring 302, the first electrode in the second light-emitting element 202 is connected to the third sub-wiring 303, and the first electrode in the third light-emitting element 203 is connected to the fourth sub-wiring 304. The wiring layer 300 may be formed together on the filling layer 210.

The wiring layer 300 has opposite upper and lower surfaces, the lower surface of the wiring layer 300 is in contact with the filling layer 210 and the light-emitting elements 200, and the upper surface of the wiring layer 300 is used to form the insulation layer 400.

The wiring layer 300 may be a single layer or a multi-layer made of at least one material such as titanium, copper, chromium, nickel, gold, platinum, aluminum, titanium nitride, tantalum nitride, or tantalum. In this embodiment, the wiring layer 300 may include a first layer 310 and a second layer 320. The first layer 310 is in direct contact with the light-emitting elements 200, and the second layer 320 is formed on the first layer 310. The first layer 310 is used to adhere the second layer 320 to the light-emitting elements 200 and the filling layer 210, and the second layer 320 mainly plays a conductive role. A material of the first layer 310 includes but is not limited to one or more of titanium, nickel, titanium nitride, tantalum nitride, or tantalum, and a material of the second layer 320 includes but is not limited to one or more of copper, aluminum, or gold. The wiring layer 300 can be prepared by sputtering, evaporation and the like.

In an embodiment, the thickness of the wiring layer 300 is in a range of 50-1000 nm, in which a thickness of the first layer 310 is in a range of 10-200 nm, a thickness of the second layer 320 is in a range of 200-800 nm, and the thickness of the first layer 310 is less than that of the second layer 320.

In an embodiment, referring to FIGS. 1 and 2, the conductive pad 500 is formed on a side of the wiring layer 300 facing away from the light-emitting elements 200, and is electrically connected to the light-emitting elements 200 through the wiring layer 300.

The conductive pad 500 includes a first sub-pad 501, a second sub-pad 502, a third sub-pad 503 and a fourth sub-pad 504. The first sub-pad 501 serves as a common sub-pad, and the first electrodes in the first light-emitting element 201, the second light-emitting element 202 and the third light-emitting element 203 are connected to the first sub-pad 501 through the first sub-wiring 301. The second electrode of the first light-emitting element 201 is connected to the second sub-pad 502 through the second sub-wiring 302, the second electrode of the second light-emitting element 202 is connected to the third sub-pad 503 through the third sub-wiring 303, and the second electrode of the third light-emitting element 203 is connected to the fourth sub-pad 504 through the fourth sub-wiring 304.

Alternatively, the first sub-pad 501 serves as the common sub-pad, and the second electrodes of the first light-emitting element 201, the second light-emitting element 202 and the third light-emitting element 203 are connected to the first sub-pad 501 through the first sub-wiring 301. The first electrode of the first light-emitting element 201 is connected to the second sub-pad 502 through the second sub-wiring 302, the first electrode of the second light-emitting element 202 is connected to the third sub-pad 503 through the third sub-wiring 303, and the first electrode of the third light-emitting element 203 is connected to the fourth sub-pad 504 through the fourth sub-wiring 304.

In an embodiment, the conductive pad 500 includes a conductive layer 510, the conductive layer 510 may be a single layer or a multi-layer made of at least one material such as titanium, copper, gold, platinum, etc., and a thickness of the conductive layer 510 is in a range of 10-50 μm, for example, 20 μm, 30 μm, 40 μm.

As an alternative embodiment, referring to FIG. 2, the conductive pad 500 includes the conductive layer 510 and a protective layer 530 sequentially formed on the wiring layer 300. Before the light-emitting module is installed in the display apparatus, the protective layer 530 completely covers an upper surface of the conductive layer 510, which can effectively prevent the conductive layer 510 from being oxidized and improve the stability of the light-emitting module. When the light-emitting module is installed in the display apparatus, the protective layer 530 will be damaged or removed. The protective layer 530 does not affect the bonding and conductivity of the conductive pad 500, and a thickness of the protective layer 530 is in a range of 25-50 nm.

The protective layer 530 can be made of metal materials such as gold and platinum. In the process of installing the light-emitting module in the display apparatus, the conductive pad 500 and a circuit board are soldered with a soldering material at a preset temperature. During the soldering process, the soldering material flows and deforms, and the deformation of the soldering material can destroy the integrity of the protective layer 530 made of metal materials such as gold and platinum.

Alternatively, the protective layer 530 can be an organic material such as organic solderability preservative (OSP). During the installation of the light-emitting module in the display apparatus, the conductive pad 500 and the circuit board are soldered with a soldering material at a preset temperature, and the organic material such as OSP is dissolved at this temperature to be removed.

In an embodiment, an adhesive layer 520 is also provided between the conductive layer 510 and the protective layer 530. The adhesive layer 520 may be a single layer or a multi-layer made of at least one material of chromium, titanium, nickel, tantalum nitride, tantalum and the like. A thickness of the adhesive layer 520 is in a range of 3-5 μm.

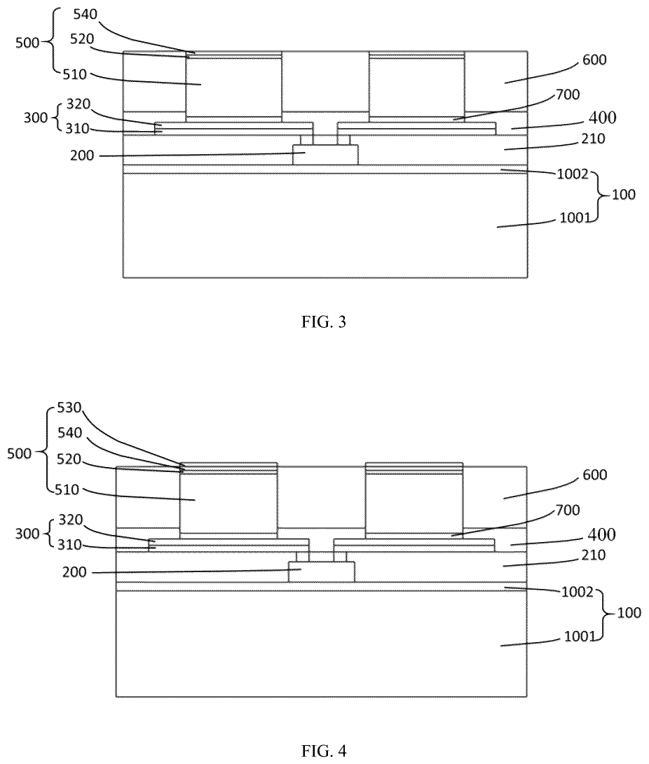

As an alternative embodiment, referring to FIG. 3, the conductive pad 500 includes the conductive layer 510 and a eutectic layer 540 sequentially formed on the wiring layer 300. The eutectic layer 540 may be a single layer or a multi-layer made of at least one material such as tin (Sn), tin-silver (SnAg), gold-tin (AuSn), etc., and a thickness of the eutectic layer 540 is in a range of 10-50 nm. The eutectic layer 540 can effectively increase the bonding force of the light-emitting module when it is applied to the circuit board, and the solder paste does not need to be printed again or only a small amount of solder paste needs to be brushed during application, thus improving the convenience of the client.

In an embodiment, an adhesive layer 520 is also provided between the conductive layer 510 and the eutectic layer 540. The adhesive layer 520 may be a single layer or a multi-layer made of at least one material of chromium, titanium, nickel, tantalum nitride, tantalum and the like. A thickness of the adhesive layer 520 is in a range of 3-5 μm.

In an embodiment, referring to FIG. 4, a side of the eutectic layer 540 facing away from the conductive layer 510 is also provided with a protective layer 530, and a structure of the protective layer 530 is the same as that of the protective layer 530 in the above embodiment.

In an embodiment, referring to FIGS. 2-4, an encapsulation layer 600 is filled around the conductive pad 500 to electrically isolate adjacent sub-pads. The encapsulation layer 600 is provided as a light-absorbing adhesive layer, and is specifically a component formed by dispersing a black filler component in transparent or translucent materials such as silica gel, epoxy resin, polyimide, low-temperature glass, polysiloxane and polysilazane, and the black filler component in the encapsulation layer 600 includes but are not limited to carbon black, titanium nitride, iron oxide, ferroferric oxide and iron powder.

Since the light-emitting elements 200 and the wiring layer 300 are relatively thin, the encapsulation layer 600 has a certain thickness to protect the light-emitting elements 200 and the wiring layer 300 from damage from external factors, and a thickness of the encapsulation layer 600 is greater than 20 μm. At this time, the thickness of the conductive pad 500 is also greater than 20 μm. The encapsulation layer 600 is doped with doped particles with a particle size greater than 1 μm, such as silicon dioxide, which can enhance the mechanical properties of the encapsulation layer 600, thus better protecting the light-emitting elements 200 and the wiring layer 300.

In an embodiment, as illustrated in FIG. 2, a surface of the encapsulation layer 600 facing away from the wiring layer 300 is flush with a surface of the conductive layer 510 of the conductive pad 500 facing away from the wiring layer 300.

In an embodiment, as illustrated in FIGS. 3 and 4, the surface of the encapsulation layer 600 facing away from the wiring layer 300 is flush with a surface of the eutectic layer 540 of the conductive pad 500 facing away from the wiring layer 300, so that the surface of the light-emitting module becomes flat, which is beneficial to the use of the client.

In an embodiment, the thickness of the conductive pad 500 is greater than or equal to 5 μm, which can be formed by electroplating.

In an embodiment, referring to FIGS. 2 to 4, the insulation layer 400 is located on the upper surface of the wiring layer 300 and fills the periphery in the wiring layer 300. The insulation layer 400 is defined with through holes located above the wiring layer 300 and used to form the conductive pad 500. The number of the through holes is the same as that of the sub-pads of the conductive pad 500, that is, one sub-pad corresponds to one through hole.

The insulation layer 400 can be a component made of materials such as epoxy resin, polysiloxane or photoresist, which can prevent the wiring layer 300 from being oxidized, electrically isolate different wirings, and avoid the phenomenon of leakage failure of the light-emitting module.

The upper surface of the wiring layer 300 is provided with a seed layer 700, and the seed layer 700 conducts electricity to prepare the conductive pad 500 by electroplating. The seed layer 700 may be a single layer or a multi-layer made of at least one material of titanium, copper, gold and platinum. In this embodiment, the seed layer 700 is a titanium/copper (Ti/Cu) stacked layer with a thickness of 100-2000 nm.

### Embodiment 2

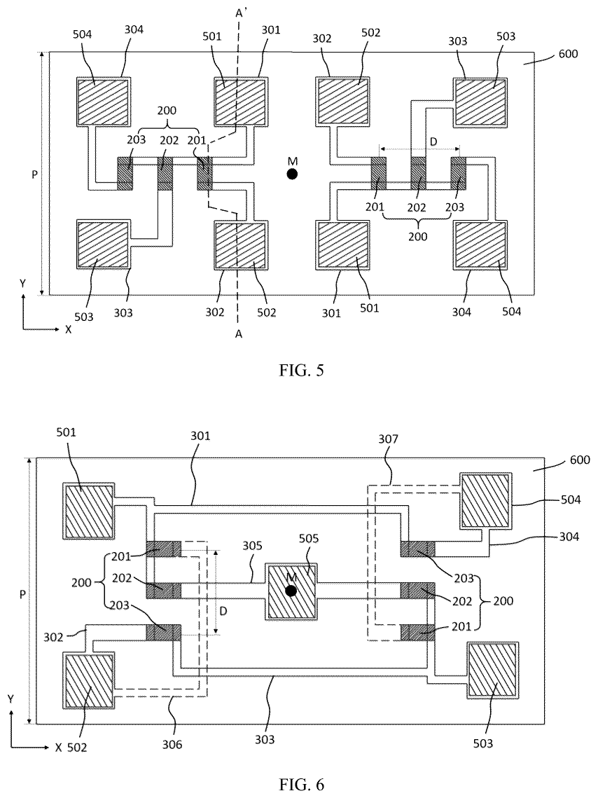

FIG. 5 illustrates a schematic plan view of a light-emitting module according to an embodiment 2 of the disclosure. Different from the embodiment 1, the light-emitting module includes multiple groups of light-emitting elements 200 arranged in a centrosymmetric manner.

As illustrated in FIG. 5, the light-emitting module includes multiple groups of light-emitting elements 200 arranged in the centrosymmetric manner, and each group includes multiple light-emitting elements 200 arranged at intervals with different wavelength ranges, and a gap between adjacent light-emitting elements 200 is filled with a filling layer 210 to electrically isolate the adjacent light-emitting elements 200. The wiring layer 300 is arranged in the centrosymmetric manner, which is formed on the multiple groups of light-emitting elements 200 and configured to electrically connect to the light-emitting elements 200. The conductive pad 500 is arranged in the centrosymmetric manner, which are formed on a side of the wiring layer 300 facing away from the light-emitting elements 200 and is electrically connected to the light-emitting elements 200 through the wiring layer 300. The multiple groups of light-emitting elements 200, the wiring layer 300, and the conductive pads 500 are symmetrical about a center point M of the light-emitting module.

Since the multiple groups of light-emitting elements 200, the wiring layer 300 and the conductive pad 500 in the light-emitting module are all arranged in the centrosymmetric manner, a structure of the light-emitting module has good symmetry. After the treatment of the light-emitting module, when the light-emitting module is rearranged by using a vibrating plate, a horizontal direction of the light-emitting module is not needed to be judged, but only a vertical direction of the light-emitting module is judged, which effectively shortens the time required for rearranging the light-emitting module and greatly improves the production efficiency. At the same time, the structure of the vibrating plate can be simplified and the production cost can be reduced.

In an embodiment, as illustrated in FIG. 5, the light-emitting module includes multiple pixel units, and each pixel unit corresponds to the above-mentioned group of light-emitting elements. The multiple pixel units are arranged in columns in a first direction X or in rows in a second direction Y, and the first direction X is perpendicular to the second direction Y. An arrangement direction of the light-emitting elements 200 in each pixel unit is parallel to an arrangement direction of the pixel units. Center points of the light-emitting elements 200 in the multiple pixel units are all on the same axis. The multiple groups of light-emitting elements 200 are symmetrical about an axis extending along a first preset direction and passing through the center point M of the light-emitting module, and the first preset direction is perpendicular to the arrangement direction of the pixel units.

The conductive pad 500 includes m×(1+n) sub-pads, where m is the number of groups of light-emitting elements 200 and n is the number of light-emitting elements 200 included in each group. In this embodiment, the number of groups of light-emitting elements 200 included in the light-emitting module is even integer, and the number of groups of light-emitting elements 200 included in the light-emitting module is specifically two, and the number of light-emitting elements 200 included in each group is three.

As an alternative embodiment, the arrangement direction of the light-emitting elements 200 in each pixel unit is perpendicular to the arrangement direction of the pixel units. The multiple groups of light-emitting elements 200 are symmetrical about the center point M of the light-emitting module. The conductive pad 500 includes m×(1+n) sub-pads, where m is the number of groups of light-emitting elements 200 and n is the number of light-emitting elements 200 included in each group.

In an embodiment, as illustrated in FIG. 5, each group of light-emitting elements 200 includes a first light-emitting element 201, a second light-emitting element 202 and a third light-emitting element 203 sequentially arranged in that order. A spacing between the first light-emitting element 201 and the third light-emitting element 203 is D, a width of the light-emitting module in the first preset direction is P, and a value of D/P is less than or equal to 0.15, so as to ensure that the light-emitting module is visually consistent in color distribution. In this embodiment, the first light-emitting element 201, the second light-emitting element 202 and the third light-emitting element 203 radiate light in different wavelength ranges, for example, the first light-emitting element 201 radiates blue light, the second light-emitting element 202 radiates green light, and the third light-emitting element 203 radiates red light.

In an embodiment, as illustrated in FIG. 5, the light-emitting module includes two groups of light-emitting elements 200, and the two groups of light-emitting elements 200 are arranged in columns according to the first direction X. Each group of light-emitting elements 200 includes a first light-emitting element 201, a second light-emitting element 202 and a third light-emitting element 203 sequentially arranged in that order in the first direction X. The two groups of light-emitting elements 200 are symmetrically arranged about the axis extending in the second direction Y and passing through the center point M of the light-emitting module. In other words, the arrangement orders of the light-emitting elements 200 in the two groups of light-emitting elements 200 are opposite.

The wiring layers 300 corresponding to the two groups of light-emitting elements 200 are symmetrical about the center point M of the light-emitting module. The wiring layer 300 corresponding to each group of light-emitting elements 200 includes a first sub-wiring 301, a second sub-wiring 302, a third sub-wiring 303 and a fourth sub-wiring 304. The first sub-wiring 301 serves as a common wiring, first electrodes of the first light-emitting element 201, the second light-emitting element 202 and the third light-emitting element 203 are connected to the first sub-wiring 301. A second electrode in the first light-emitting element 201 is connected to the second sub-wiring 302, a second electrode in the second light-emitting element 202 is connected to the third sub-wiring 303, and a second electrode in the third light-emitting element 203 is connected to the fourth sub-wiring 304.

Alternatively, the first sub-wiring 301 serves as the common wiring, and the second electrodes in the first light-emitting element 201, the second light-emitting element 202 and the third light-emitting element 203 are connected to the first sub-wiring 301, the first electrode in the first light-emitting element 201 is connected to the second sub-wiring 302, the first electrode in the second light-emitting element 202 is connected to the third sub-wiring 303, and the first electrode in the third light-emitting element 203 is connected to the fourth sub-wiring 304.

It should be noted that shapes of the above two sub-wirings which should be arranged in the centrosymmetric manner may be the same or different. When the shapes of the two sub-wirings that should be arranged in the centrosymmetric manner are the same, the shapes and layout modes of all the sub-wirings are symmetrical about the center point M of the light-emitting module. When the shapes of the two sub-wirings that should be arranged in the centrosymmetric manner are different, the layout modes of all the sub-wirings are symmetrical about the center point M of the light-emitting module.

The conductive pads 500 corresponding to the two groups of light-emitting elements 200 are symmetrical about the center point M of the light-emitting module. The conductive pad 500 corresponding to each group of light-emitting elements 200 includes a first sub-pad 501, a second sub-pad 502, a third sub-pad 503 and a fourth sub-pad 504. The first sub-pad 501 serves as a common sub-pad, and the first electrodes of the first light-emitting element 201, the second light-emitting element 202 and the third light-emitting element 203 are connected to the first sub-pad 501 through the first sub-wiring 301. The second electrode of the first light-emitting element 201 is connected to the second sub-pad 502 through the second sub-wiring 302, the second electrode of the second light-emitting element 202 is connected to the third sub-pad 503 through the third sub-wiring 303, and the second electrode of the third light-emitting element 203 is connected to the fourth sub-pad 504 through the fourth sub-wiring 304.

Alternatively, the first sub-pad 501 serves as the common sub-pad, and the second electrodes of the first light-emitting element 201, the second light-emitting element 202 and the third light-emitting element 203 are connected to the first sub-pad 501 through the first sub-wiring 301. The first electrode of the first light-emitting element 201 is connected to the second sub-pad 502 through the second sub-wiring 302, the first electrode of the second light-emitting element 202 is connected to the third sub-pad 503 through the third sub-wiring 303, and the first electrode of the third light-emitting element 203 is connected to the fourth sub-pad 504 through the fourth sub-wiring 304.

It should be noted that the shapes of the two sub-pads that should be arranged in the centrosymmetric manner may be the same or different. When the shapes of the two sub-pads that should be arranged in the centrosymmetric manner are the same, the shapes and layout modes of all the sub-pads are symmetrical about the center point M of the light-emitting module. When the shapes of the two sub-pads which should be arranged in the centrosymmetric manner are different, the layout modes of all the sub-pads are symmetrical about the center point M of the light-emitting module.

### Embodiment 3

FIG. 6 illustrates a schematic plan view of a light-emitting module according to an embodiment 3 of the disclosure. Different from the first embodiment, the light-emitting module includes multiple groups of light-emitting elements 200 arranged in a centrosymmetric manner.

As illustrated in FIG. 6, the light-emitting module includes multiple groups of light-emitting elements 200 arranged in the centrosymmetric manner, and each group includes multiple light-emitting elements 200 arranged at intervals with different wavelength ranges, and a gap between adjacent light-emitting elements 200 is filled with a filling layer 210 to electrically isolate the adjacent light-emitting elements 200. A wiring layer 300 is arranged in the centrosymmetric manner, which is formed on the multiple groups of light-emitting elements 200 and configured to electrically connect to the light-emitting elements 200. A conductive pad 500 is arranged in the centrosymmetric manner, is formed on a side of the wiring layer 300 facing away from the light-emitting elements 200 and is electrically connected to the light-emitting elements 200 through the wiring layer 300. The multiple groups of light-emitting elements 200, the wiring layer 300, and the conductive pad 500 are symmetrical about the center point M of the light-emitting module.

Since multiple groups of light-emitting elements 200, the wiring layer 300 and the conductive pad 500 in the light-emitting module are all arranged in the centrosymmetric manner, a structure of the light-emitting module has good symmetry. After the treatment of the light-emitting module, when the light-emitting module is rearranged by using a vibrating plate, a horizontal direction of the light-emitting module is not needed to be judged, but only a vertical direction of the light-emitting module is judged, which effectively shortens the time required for rearranging the light-emitting module and greatly improves the production efficiency. At the same time, the structure of the vibrating plate can be simplified and the production cost can be reduced.

In an embodiment, as illustrated in FIG. 6, the light-emitting module includes multiple pixel units, and each pixel unit corresponds to the above-mentioned group of light-emitting elements. The multiple pixel units are arranged in columns in a first direction X or in rows in a second direction Y, and the first direction X is perpendicular to the second direction Y. An arrangement direction of the light-emitting elements 200 in each pixel unit is perpendicular to an arrangement direction of the pixel units. Center points of the light-emitting elements 200 in the multiple pixel units are all on the same axis. The multiple groups of light-emitting elements 200 are symmetrical about the center point M of the light-emitting module.

The conductive pad 500 includes 2 m+1 sub-pads, where m is the number of groups of light-emitting elements 200. A central area of the light-emitting module is provided with a sub-pad. In this embodiment, the number of groups of light-emitting elements 200 included in the light-emitting module is even integer, and the number of groups of light-emitting elements 200 included in the light-emitting module is two, and the number of light-emitting elements 200 included in each group is three.

In an embodiment, as illustrated in FIG. 6, each group of light-emitting elements 200 includes a first light-emitting element 201, a second light-emitting element 202 and a third light-emitting element 203 sequentially arranged in that order. A spacing between the first light-emitting element 201 and the third light-emitting element 203 is D, a width of the light-emitting module in a direction perpendicular to the arrangement direction of the pixel units is P, and a value of D/P is less than or equal to 0.15, so as to ensure that the light-emitting module is visually consistent in color distribution. In this embodiment, the first light-emitting element 201, the second light-emitting element 202 and the third light-emitting element 203 radiate light in different wavelength ranges, for example, the first light-emitting element 201 radiates blue light, the second light-emitting element 202 radiates green light and the third light-emitting element 203 radiates red light.

In an embodiment, as illustrated in FIG. 6, the light-emitting module includes two groups of light-emitting elements 200, and the two groups of light-emitting elements 200 are arranged in columns according to the first direction X. Each group of light-emitting elements 200 includes a first light-emitting element 201, a second light-emitting element 202 and a third light-emitting element 203 sequentially arranged in the second direction Y, and the two groups of light-emitting elements 200 are symmetrically arranged about the center point M of the light-emitting module. In other words, the arrangement orders of the light-emitting elements 200 in the two groups of light-emitting elements 200 are opposite.

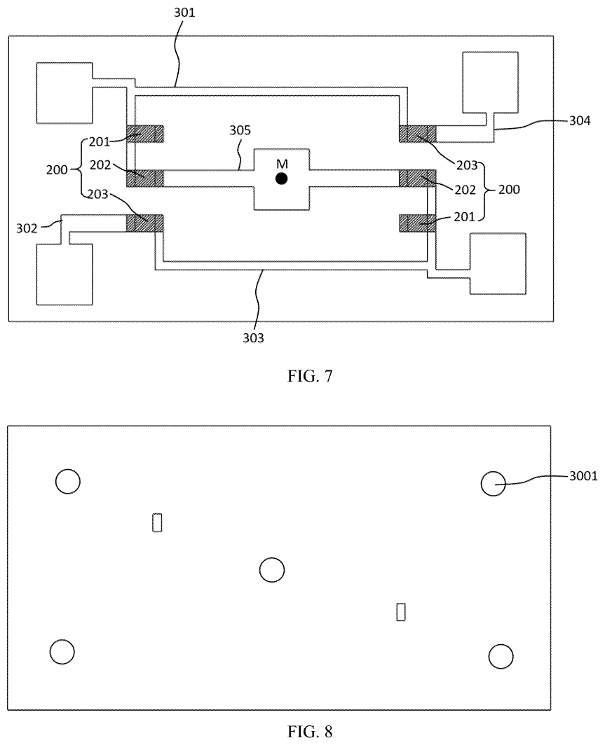

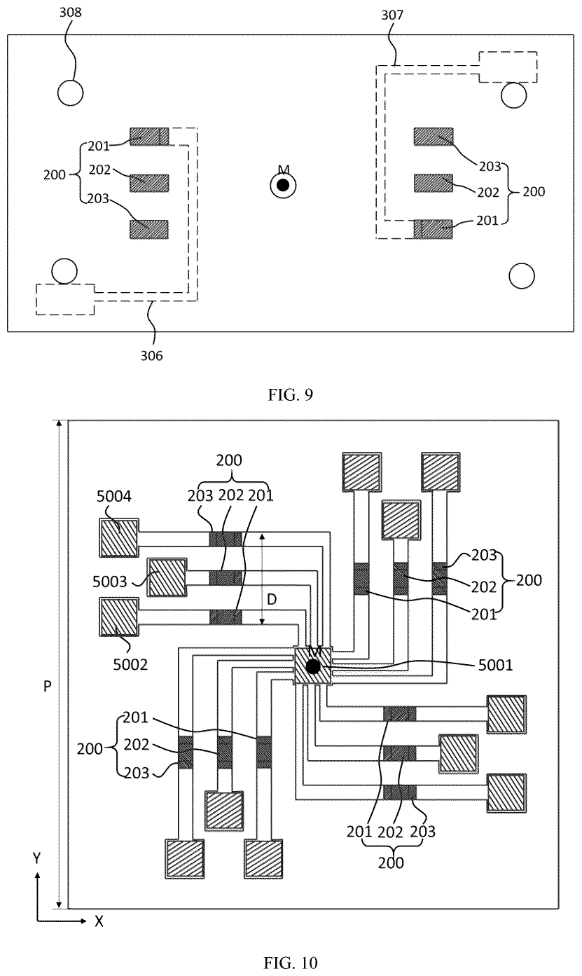

The wiring layers 300 corresponding to the two groups of light-emitting elements 200 are symmetrical about the center point M of the light-emitting module. The wiring layer 300 includes a first wiring layer, a through-hole layer and a second wiring layer. A wiring schematic diagram of the first wiring layer is illustrated in FIG. 7, the through-hole layer is illustrated in FIG. 8, and a wiring schematic diagram of the second wiring layer is illustrated in FIG. 9.

As illustrated in FIG. 7, the first wiring layer includes a first sub-wiring 301, a second sub-wiring 302, a third sub-wiring 303, a fourth sub-wiring 304 and a fifth sub-wiring 305. The first sub-wiring 301 and the third sub-wiring 303 are symmetrical about the center point M of the light-emitting module, the second sub-wiring 302 and the fourth sub-wiring 304 are symmetrical about the center point M of the light-emitting module, and the fifth sub-wiring 305 is symmetrical about the center point M of the light-emitting module.

First electrodes of the first light-emitting element 201 and the second light-emitting element 202 in the first group of light-emitting elements, a second electrode of the third light-emitting element 203 in the second group of light-emitting elements are connected to the first sub-wiring 301. A first electrode of the third light-emitting element 203 in the first group of light-emitting elements is connected to the second sub-wiring 302. A second electrode of the third light-emitting element 203 in the first group of light-emitting elements, and first electrodes of the first light-emitting element 201 and the second light-emitting element 202 in the second group of light-emitting elements are connected to the third sub-wiring 303. A first electrode of the third light-emitting element 203 in the second group of light-emitting elements is connected to the fourth sub-wiring 304. The second electrodes of the second light-emitting elements 202 in the two groups of light-emitting elements are connected to the fifth sub-wiring 305.

As illustrated in FIG. 8, the through-hole layer includes several through holes 3001, and specifically includes through holes located above the first sub-wiring 301, the second sub-wiring 302, the third sub-wiring 303, the fourth sub-wiring 304 and the fifth sub-wiring 305, and through holes located above the second electrode in the first light-emitting element 201.

As illustrated in FIG. 9, the second wiring layer includes a sixth sub-wiring 306 and a seventh sub-wiring 307, and the sixth sub-wiring 306 and the seventh sub-wiring 307 are symmetrical about the center point M of the light-emitting module. The sixth sub-wiring 306 and the seventh sub-wiring 307 are respectively used to connect to the second electrodes of the first light-emitting elements 201 in the two groups of light-emitting elements.

In an embodiment, the second wiring layer further includes multiple interconnect sub-wirings 308, and the multiple interconnect sub-wirings 308 are symmetrical about the center point M of the light-emitting module. The multiple interconnect sub-wirings 308 are respectively formed in the through holes above the first sub-wiring 301, the second sub-wiring 302, the third sub-wiring 303, the fourth sub-wiring 304 and the fifth sub-wiring 305, and are respectively connected to the first sub-wiring 301, the second sub-wiring 302, the third sub-wiring 303, the fourth sub-wiring 304 and the fifth sub-wiring 305, to lead out the first sub-wiring 301, the second sub-wiring 302, the third sub-wiring 303, the fourth sub-wiring 304 and the fifth sub-wiring 305.

It should be noted that the shapes of the above two sub-wirings which should be arranged in the centrosymmetric manner may be the same or different. When the shapes of the two sub-wirings that should be arranged in the centrosymmetric manner are the same, the shapes and layout modes of all the sub-wirings are symmetrical about the center point M of the light-emitting module. When the shapes of the two sub-wirings that should be arranged in the centrosymmetric manner are different, the layout modes of all the sub-wirings are symmetrical about the center point M of the light-emitting module.

The conductive pads 500 corresponding to the two groups of light-emitting elements 200 are symmetrical about the center point M of the light-emitting module. The conductive pad 500 includes a first sub-pad 501, a second sub-pad 502, a third sub-pad 503, a fourth sub-pad 504 and a fifth sub-pad 505. The first sub-pad 501 is electrically connected to the first sub-wiring 301. The second sub-pad 502 is electrically connected to the second sub-wiring 302 and the sixth sub-wiring 306. The third sub-pad 503 is electrically connected to the third sub-wiring 303. The fourth sub-pad 504 is electrically connected to the fourth sub-wiring 304 and the seventh sub-wiring 307. The fifth sub-pad 505 is electrically connected to the fifth sub-wiring 305. In an embodiment, the first sub-wiring 301, the second sub-wiring 302, the third sub-wiring 303, the fourth sub-wiring 304 and the fifth sub-wiring 305 are respectively connected to their corresponding sub-pads through the interconnect sub-wirings 308.

It should be noted that the shapes of the two sub-pads that should be arranged in the centrosymmetric manner may be the same or different. When the shapes of the two sub-pads that should be arranged in the centrosymmetric manner are the same, the shapes and layout modes of all the sub-pads are symmetrical about the center point M of the light-emitting module. When the shapes of the two sub-pads which should be arranged in the centrosymmetric manner are different, the layout modes of all the sub-pads are symmetrical about the center point M of the light-emitting module.

### Embodiment 4

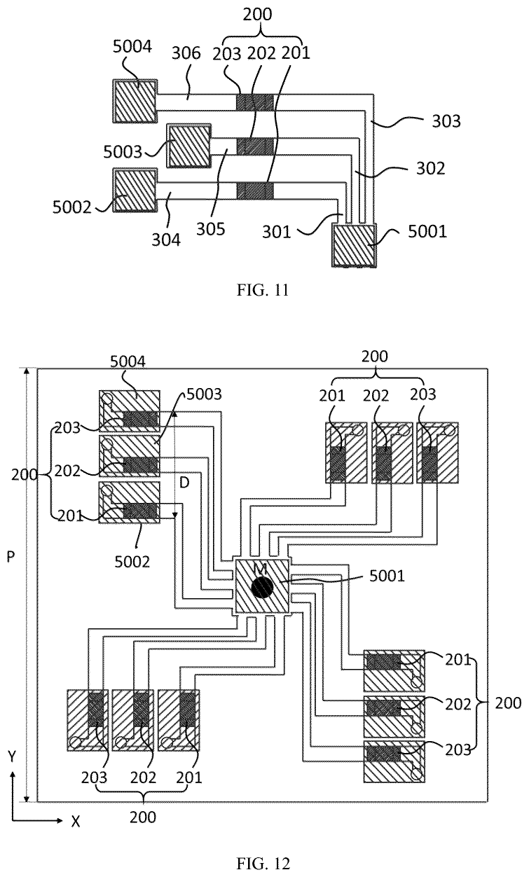

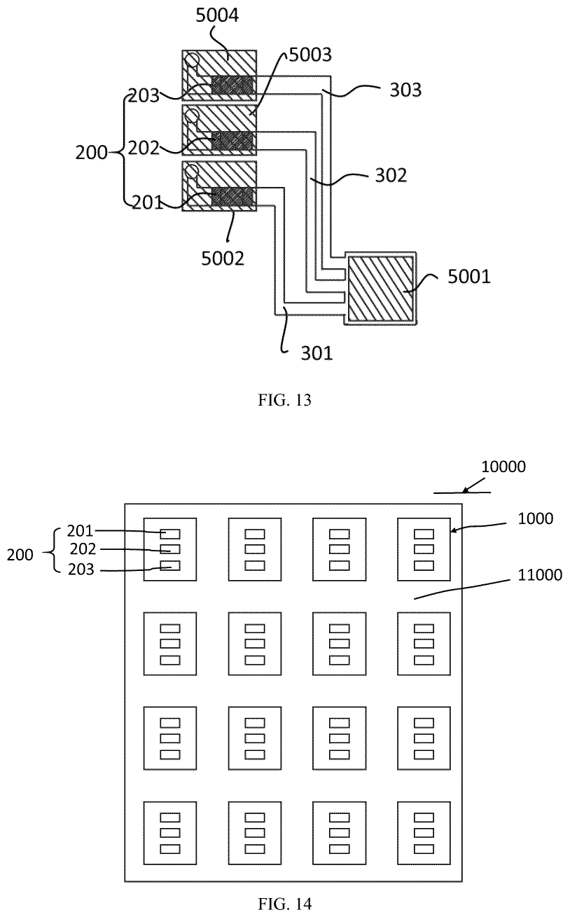

FIGS. 10 and 12 illustrate schematic top views of a light-emitting module according to an embodiment 4 of the disclosure. Different from the embodiment 1, the light-emitting module includes multiple groups of light-emitting elements 200 arranged in a centrosymmetric manner.

As illustrated in FIG. 10 and FIG. 12, the light-emitting module includes multiple groups of light-emitting elements 200 arranged in the centrosymmetric manner, each group including multiple light-emitting elements 200 arranged at intervals with different wavelength ranges, and a gap between adjacent light-emitting elements 200 is filled with a filling layer 210 to electrically isolate the adjacent light-emitting elements 200. The wiring layer 300 is arranged in the centrosymmetric manner, which is formed on the multiple groups of light-emitting elements 200 and configured to electrically connect to the light-emitting elements 200. The conductive pad 500 is arranged in the centrosymmetric manner, is formed on a side of the wiring layer 300 facing away from the light-emitting elements 200 and is electrically connected to the light-emitting elements 200 through the wiring layer 300. The multiple groups of light-emitting elements 200, the wiring layer 300, and the conductive pad 500 are symmetrical about the center point M of the light-emitting module.

Since the multiple groups of light-emitting elements 200, the wiring layers 300 and conductive pads 500 in the light-emitting module are all arranged in the centrosymmetric manner, a structure of the light-emitting module has good symmetry. After the treatment of the light-emitting module, when the light-emitting module is rearranged by using a vibrating plate, a horizontal direction of the light-emitting module is not needed to be judged, but only a vertical direction of the light-emitting module is judged, which effectively shortens the time required for rearranging the light-emitting module and greatly improves the production efficiency. At the same time, the structure of the vibrating plate can be simplified and the production cost can be reduced.

In an embodiment, as illustrated in FIGS. 10 and 12, the light-emitting module includes multiple pixel units, and each pixel unit corresponds to the above-mentioned group of light-emitting elements. The multiple pixel units are arranged in columns according to a first direction X and in rows according to a second direction Y, and the first direction X is perpendicular to the second direction Y. Widths of the light-emitting module in the first direction X and the second direction Y are less than or equal to 3 millimeters (mm), specifically less than or equal to 2 mm or 1.6 mm, and widths of the light-emitting element 200 in the first direction X and the second direction Y is less than or equal to 100 μm.

In two adjacent pixel units, arrangement directions of the light-emitting elements 200 in the two pixel units are vertical, that is, the light-emitting elements 200 in one pixel unit are arranged along the first direction X, and the light-emitting elements 200 in the other pixel unit are arranged along the second direction Y. The center points of the light-emitting elements 200 in the two pixel units are on the same axis. It should be noted that the above two adjacent pixel units may refer to two adjacent pixel units in the first direction X or two adjacent pixel units in the second direction Y.

The conductive pad 500 includes 1+m×n sub-pads, where m is the number of groups of light-emitting elements 200 and n is the number of light-emitting elements 200 included in each group. In this embodiment, the number of groups of light-emitting elements 200 included in the light-emitting module is four, and the number of light-emitting elements 200 included in each group is three.

In an embodiment, as illustrated in FIG. 10 and FIG. 12, each group of light-emitting elements 200 includes a first light-emitting element 201, a second light-emitting element 202 and a third light-emitting element 203 sequentially arranged in that order. A spacing between the first light-emitting element 201 and the third light-emitting element 203 is D, a width of the light-emitting module in the first direction X or the second direction Y is P, and a value of D/P is less than or equal to 0.15, so as to ensure that the light-emitting module is visually consistent in color distribution. In this embodiment, the first light-emitting element 201, the second light-emitting element 202 and the third light-emitting element 203 radiate light in different wavelength ranges, for example, the first light-emitting element 201 radiates blue light, the second light-emitting element 202 radiates green light, and the third light-emitting element 203 radiates red light.

In an embodiment, as illustrated in FIGS. 10 and 12, the conductive pad 500 includes a common sub-pad 5001 and several independent sub-pads. The common sub-pad 5001 is located in a central area of the light-emitting module, and the number of independent sub-pads corresponds to the number of light-emitting elements 200. The common sub-pad 5001 is an anode pad, anodes of all light-emitting elements 200 are connected to the common sub-pad 5001, and cathodes of each light-emitting element 200 are respectively connected to their corresponding independent sub-pads. Alternatively, the common sub-pad 5001 is a cathode pad, and the cathodes of all light-emitting elements 200 are connected to the common sub-pad 5001, and the anodes of each light-emitting element 200 are respectively connected to their corresponding independent sub-pads.

This co-anode/cathode connection can make the light-emitting module with small spacing pixels have more space for wiring design, and through the co-anode/cathode connection, four groups of light-emitting elements 200 can be gathered together to form a four-in-one light-emitting module. The light-emitting module can be overlapped with a layout of the light-emitting module before being rotated by 90 degrees in any direction, which can improve the alignment accuracy and reduce the alignment difficulty when the light-emitting module is transferred and aligned.

In an embodiment, as illustrated in FIG. 10, at least some independent sub-pads are not located above the light-emitting element 200, and widths of the common sub-pad 5001 and the independent sub-pads not located above the light-emitting element in the first direction X and the second direction Y are in a range of 120-200 μm. In this embodiment, all the independent sub-pads are not located above the light-emitting elements 200.

In an embodiment, as illustrated in FIG. 12, at least some of the independent sub-pads are located above the light-emitting elements 200, and the widths of the common sub-pad 5001 and the independent sub-pads located above the light-emitting elements in the first direction X and the second direction Y are in a range of 200-300 μm. In this embodiment, the independent sub-pads are all located above the light-emitting elements 200. When the independent sub-pads are located above the light-emitting element 200, the design widths of the common sub-pads 5001 and the independent sub-pads can be made larger, and the overall width of the light-emitting module can be made smaller.

In an embodiment, as illustrated in FIG. 10, the light-emitting module includes four groups of light-emitting elements 200, and the four groups of light-emitting elements 200 are arranged in two columns according to the first direction X and two rows according to the second direction Y. In particular, the group of light-emitting elements in the first row and the first column is abbreviated as D11, the group of light-emitting elements in the first row and the second column is abbreviated as D12, the group of light-emitting elements in the second row and the first column is abbreviated as D21, and the group of light-emitting elements in the second row and the second column is abbreviated as D22. The arrangement directions of the light-emitting elements 200 in D11 and D22 are parallel to each other, and the arrangement directions of the light-emitting elements 200 in D12 and D21 are parallel to each other and perpendicular to the arrangement directions of the light-emitting elements 200 in D11 and D22. In this embodiment, the light-emitting elements 200 in D11 and D22 are both arranged in the first direction X, and the light-emitting elements 200 in D12 and D21 are both arranged in the second direction Y. The four groups of light-emitting elements 200 are symmetrically arranged about the center point M of the light-emitting module.

The wiring layers 300 corresponding to the four groups of light-emitting elements 200 are symmetrical about the center point M of the light-emitting module. The wiring layer 300 corresponding to each group of light-emitting elements 200 is illustrated in FIG. 11 and includes a first sub-wiring 301, a second sub-wiring 302, a third sub-wiring 303, a fourth sub-wiring 304, a fifth sub-wiring 305 and a sixth sub-wiring 306. An anode of the first light-emitting element 201 is connected to the first sub-wiring 301, an anode of the second light-emitting element 202 is connected to the second sub-wiring 302, and an anode of the third light-emitting element 203 is connected to the third sub-wiring 303. A cathode of the first light-emitting element 201 is connected to the fourth sub-wiring 304, a cathode of the second light-emitting element 202 is connected to the fifth sub-wiring 305, and a cathode of the third light-emitting element 203 is connected to the sixth sub-wiring 306.

It should be noted that the shapes of the above two sub-wirings which should be arranged in the centrosymmetric manner may be the same or different. When the shapes of the two sub-wirings that should be arranged in the centrosymmetric manner are the same, the shapes and layout modes of all the sub-wirings are symmetrical about the center point M of the light-emitting module. When the shapes of the two sub-wirings that should be arranged in the centrosymmetric manner are different, the layout modes of all the sub-wirings are symmetrical about the center point M of the light-emitting module.

The conductive pads 500 corresponding to the four groups of light-emitting elements 200 are symmetrical about the center point M of the light-emitting module. The conductive pad 500 corresponding to each group of light-emitting elements 200 is illustrated in FIG. 11 and includes a common sub-pad 5001, a first independent sub-pad 5002, a second independent sub-pad 5003 and a third independent sub-pad 5004. The anodes of the first light-emitting element 201, the second light-emitting element 202 and the third light-emitting element 203 are respectively connected to the common sub-pad 5001 through the first sub-wiring 301, the second sub-wiring 302 and the third sub-wiring 303. The cathode of the first light-emitting element 201 is connected to the first independent sub-pad 5002 through the fourth sub-wiring 304, the cathode of the second light-emitting element 202 is connected to the second independent sub-pad 5003 through the fifth sub-wiring 305, and the cathode of the third light-emitting element 203 is connected to the third independent sub-pad 5004 through the sixth sub-wiring 306.

It should be noted that the shapes of the two sub-pads that should be arranged in the centrosymmetric manner may be the same or different. When the shapes of the two sub-pads that should be arranged in the centrosymmetric manner are the same, the shapes and layout modes of all the sub-pads are symmetrical about the center point M of the light-emitting module. When the shapes of the two sub-pads that should be arranged in the centrosymmetric manner are different, the layout modes of all the sub-pads are symmetrical about the center point M of the light-emitting module.

It should be noted that the above structure of the light-emitting module illustrated in FIG. 12 is similar to that of the light-emitting module illustrated in FIG. 10, and will not be described herein.

### Embodiment 5

FIG. 14 illustrates a schematic plan view of a display apparatus of an embodiment 5 of the disclosure.

Referring to FIG. 14, a display apparatus 10000 includes a TFT substrate 11000 and multiple light-emitting modules 1000 disposed on the TFT substrate 11000. The light-emitting modules 100 are arranged on the TFT substrate 11000 in a matrix in rows and columns, and are electrically connected to the TFT substrate 11000 respectively. The TFT substrate 11000 includes a TFT driving circuit, and the TFT driving circuit is arranged to drive the light-emitting modules 1000 in an active matrix manner. The light-emitting modules 1000 can be driven to emit light of corresponding colors through the TFT substrate 11000.

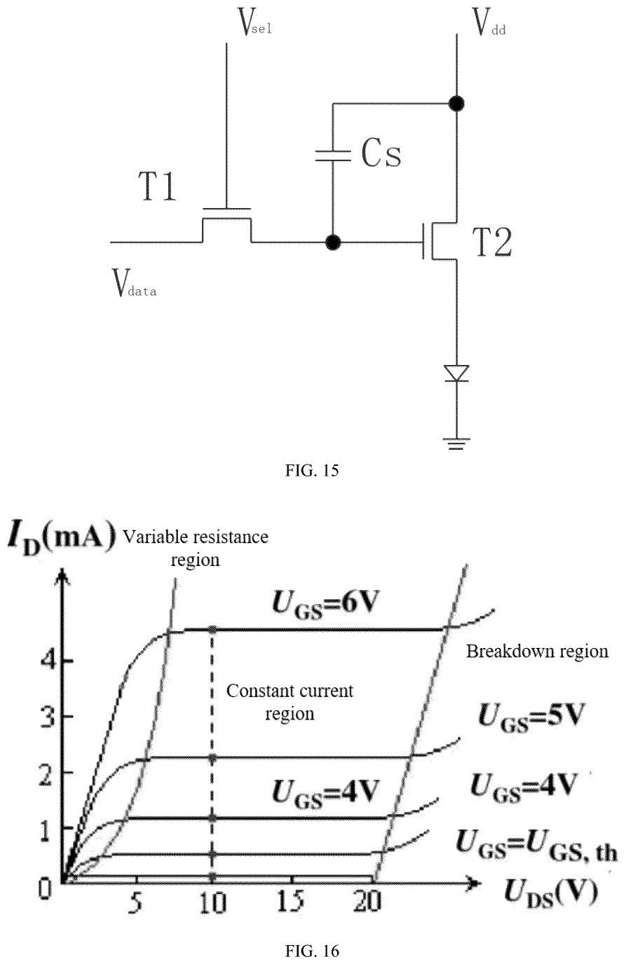

In an embodiment, a power of the TFT driving display apparatus is P≈P_{TET}+P_{LED}=I*(U_{TFT}+U_{LED}), where P_{TFT} is a power consumed by the TFT driving circuit (i.e., the TFT substrate), P_{LED} is a power consumed by the LED chip, I is an input current, U_{TFT} is a TFT driving voltage, and U_{LED} is a voltage of the LED chip. When the display apparatus is in use, P_{TFT} will be much larger than P_{LED}, and P_{TFT} is about 3-4 times that of P_{LED} at the same current. However, the function of the TFT driving circuit is to control the switch of light-emitting modules, which has no direct impact on display performance, and the power consumed by TFT driving circuit belongs to wasted power consumption. FIG. 15 illustrates a circuit diagram of the TFT driving circuit, and FIG. 16 illustrates an electrical characteristic of the TFT driving circuit. Referring to FIGS. 15 and 16, it can be seen that the current input is controlled by a data terminal input signal, and the TFT driving circuit works in a constant current region, and therefore a magnitude of the input current I is determined by a gate voltage U_{GS}. When the U_{GS} is reduced, the input current I is also reduced, and the P_{TFT} is greatly reduced, so that the power consumption of the display apparatus can be greatly reduced. However, due to the decrease of the input current I, the P_{LED} will decrease, and the photoelectric properties of the light-emitting elements may be affected, which will lead to the decrease of the performance of the display apparatus.

Therefore, according to one aspect of the disclosure, a display apparatus with low power consumption of a TFT driving circuit without affecting the photoelectric performance of the light-emitting module is provided. Referring to FIG. 14, the display apparatus 10000 includes the TFT substrate 11000 and the multiple light-emitting modules 1000 disposed on the TFT substrate 11000. The light-emitting module 1000 includes multiple light-emitting elements 200 arranged at intervals, and the multiple light-emitting elements 200 include a first light-emitting element 201 emitting a first wavelength, a second light-emitting element 202 emitting a second wavelength, and a third light-emitting element 203 emitting a third wavelength.

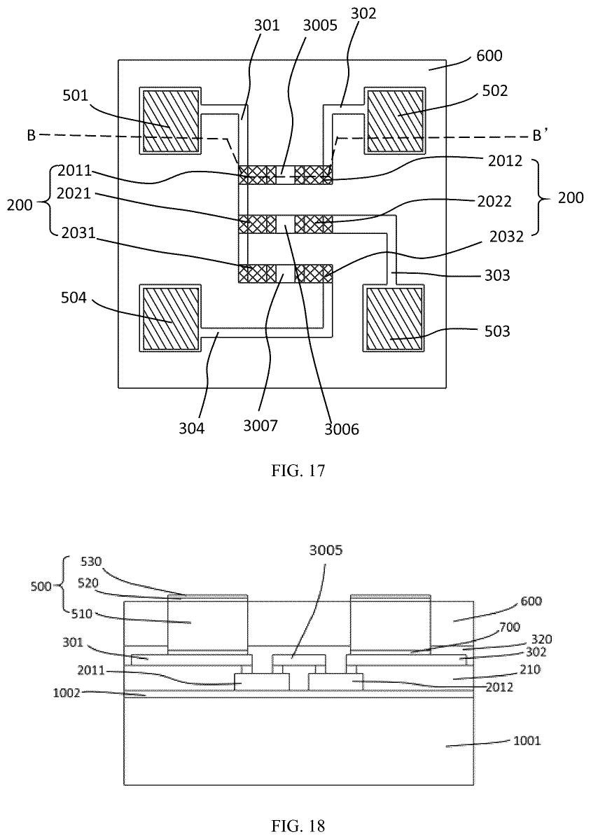

In a specific embodiment, FIG. 17 illustrates a schematic plan view of a light-emitting module of the embodiment 5 of the disclosure, and FIG. 18 illustrates a sectional view taken along a line B-B′ in FIG. 17. Referring to FIGS. 17 and 18, the light-emitting module 1000 includes multiple light-emitting elements 200 arranged at intervals, and a gap between adjacent light-emitting elements 200 is filled with a filling layer 210 to electrically isolate the adjacent light-emitting elements 200. The wiring layer 300 is formed on the multiple light-emitting elements 200 and is configured to electrically connect to the light-emitting elements 200. The conductive pad 500 is formed on a side of the wiring layer 300 facing away from the light-emitting element 200, and is electrically connected to the light-emitting element 200 through the wiring layer 300. The multiple light-emitting elements 200 include a first light-emitting element 201 emitting a first wavelength, a second light-emitting element 202 emitting a second wavelength, and a third light-emitting element 203 emitting a third wavelength. The first light-emitting element 201 includes a first light-emitting diode 2011 and a second light-emitting diode 2012 emitting the first wavelength, the second light-emitting element 202 includes a third light-emitting diode 2021 and a fourth light-emitting diode 2022 emitting the second wavelength, and the third light-emitting element 203 includes a fifth light-emitting diode 2031 and a sixth light-emitting diode 2032 emitting the third wavelength. The light-emitting diodes emitting the same wavelength are arranged in a first direction, the first light-emitting element, the second light-emitting element and the third light-emitting element are arranged in a second direction, and the first direction and the second direction are basically perpendicular.

On the premise that the display apparatus reduces the wasted power consumption of the TFT driving circuit by reducing the input current, the voltage of the light-emitting element 200 in the light-emitting module is greater than or equal to 3 volts (V) when the rated current is 1 microampere (μA). By controlling the electric power (P=IV) of the light-emitting elements to be constant, the voltage of the light-emitting elements is greater than or equal to 3 V when the light-emitting elements are connected in series, so that the display apparatus has a chance to ensure that the display performance of the light-emitting elements in the light-emitting module does not change much compared with that before the current is reduced by reducing the input current. At the same time, due to the reduction of current, the wasted power consumption of the TFT driving circuit in the display apparatus is greatly reduced, which makes the overall power of the display apparatus decrease and improves the overall service life.

In an embodiment, a spacing X1 between the light-emitting diodes emitting the same wavelength is less than 50 μm, in some display apparatus applications, the spacing X1 may be 40-50 μm, 30-40 μm, 20-30 μm, or 10-20 μm. A spacing X2 between the first light-emitting element, the second light-emitting element and the third light-emitting element is less than 50 μm, and in some display apparatus applications, the spacing X2 may be 40-50 μm, 30-40 μm, 20-30 μm, or 10-20 μm. If the spacing between light-emitting elements is greater than 50 μm, the display apparatus is prone to ghosting when viewed from a distance, and the display effect is poor.

A light-emitting area of the light-emitting element 200 is less than 30%, specifically less than 15%, or even less than 5%, for example, the light-emitting area may be 8.5%, or 2.8%, 1.125%, or even lower.

The wiring layer may include a first sub-wiring 301, a second sub-wiring 302, a third sub-wiring 303, a fourth sub-wiring 304, a first connection part 3005, a second connection part 3006 and a third connection part 3007. The first sub-wiring 301 serves as a common wiring, and first electrodes of the first light-emitting diode 2011, the third light-emitting diode 2021 and the fifth light-emitting diode 2031 are connected to the first sub-wiring 301. A second electrode of the first light-emitting diode 2011 and a first electrode of the second light-emitting diode 2012 are connected to the first connection part 3005. A second electrode of the third light-emitting diode 2021 and a first electrode of the fourth light-emitting diode 2022 are connected to the second connection part 3006. A second electrode of the fifth light-emitting diode 2031 and a first electrode of the sixth light-emitting diode 2032 are connected to the third connection part 3007. A second electrode of the second light-emitting diode 2012 is connected to the second sub-wiring 302, a second electrode of the fourth light-emitting diode 2022 is connected to the third sub-wiring 303, and a second electrode of the sixth light-emitting diode 2032 is connected to the fourth sub-wiring 304. The first light-emitting diode 2011 and the second light-emitting diode 2012 are connected in series through the first connection part 3005, the third light-emitting diode 2021 and the fourth light-emitting diode 2022 are connected in series through the second connection part 3006, and the fifth light-emitting diode 2031 and the sixth light-emitting diode 2032 are connected in series through the third connection part 3007.

The light-emitting diodes emitting the same wavelength are connected in series through the connection part, so that the voltage of the light-emitting element 200 is greater than or equal to 3 V when the rated current is 1 μA. The light-emitting diodes connected in series in the light-emitting module can increase the voltage of the light-emitting element 200 and maintain the electric power unchanged, which can avoid the reduction of the photoelectric efficiency of the light emitting element in the light emitting module due to the reduction of the input current of the display apparatus, and further affect the performance of the display apparatus.

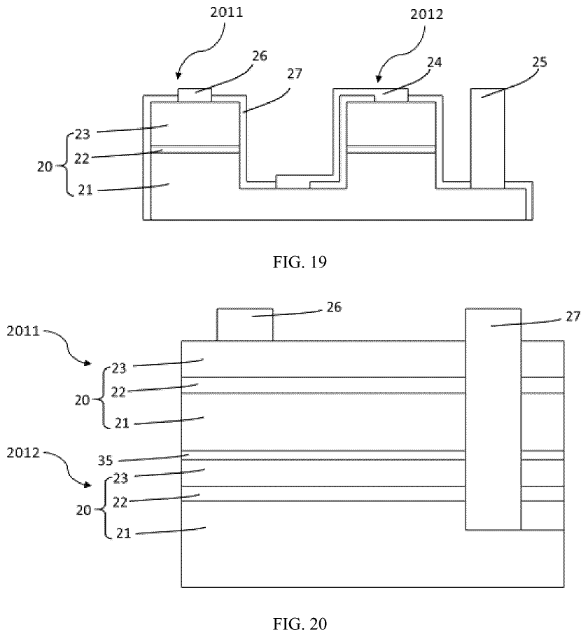

As an alternative embodiment, the plan view and the corresponding sectional view may refer to FIGS. 1 and 2. The light-emitting module includes multiple light-emitting elements 200 arranged at intervals, and the multiple light-emitting elements 200 include a first light-emitting element 201 emitting a first wavelength, a second light-emitting element 202 emitting a second wavelength, and a third light-emitting element 203 emitting a third wavelength. FIG. 19 illustrates a schematic sectional view of the first light-emitting element 201 according to an embodiment of the disclosure. In this situation, although the first light-emitting element 201 is taken as an example for description, the second light-emitting element 202 and the third light-emitting element 203 also have substantially similar structures, so repeated explanations are omitted. Referring to FIG. 19, the first light-emitting element 201 includes multiple light-emitting diodes 2011 and 2012, each of which includes a semiconductor stack 20, and the semiconductor stack 20 includes a first semiconductor layer 21, an active layer 22 and a second semiconductor layer 23. The first light-emitting element 201 includes a connection electrode 24, and the connection electrode 24 is connected to the first semiconductor layer 21 of the light-emitting diode 2011 and the second semiconductor layer 23 of the light-emitting diode 2012, so that two light-emitting diodes in the first light-emitting element 201 are connected in series. The first light-emitting element 201 further includes a first electrode 25 and a second electrode 26. The light-emitting diode 2011 has the second electrode 26 formed on the second semiconductor layer 23, and the light-emitting diode 2012 has the first electrode 25 formed on the first semiconductor layer 21. The first light-emitting element 201 further includes an insulation protective layer 27, and part of the insulation protective layer 27 is arranged between part of the connection electrode 24 and the light-emitting diodes 2011 and 2012.

As an alternative embodiment, the light-emitting module is, for example, any of the light-emitting modules described in the embodiments 1 to 4, which will not be described here again.

As an alternative embodiment, referring to FIG. 20, the first light-emitting element 201 at least includes a first light-emitting diode 2011 and a second light-emitting diode 2012. A tunneling junction 35 is formed on the second semiconductor layer 23 of the first light-emitting diode 2011, and the first semiconductor layer 21 of the second light-emitting diode 2012 is formed above the tunneling junction 35, and the first light-emitting diode 2011 and the second light-emitting diode 2012 are connected in series through the tunneling junction 35.

The light-emitting diodes emitting the same wavelength are connected in series through the connection electrode 24 or the tunneling junction 35, so that the voltage of the light-emitting element 200 is greater than or equal to 3 V when the rated current is 1 μA. The light-emitting diodes connected in series in the light-emitting module can increase the voltage of the light-emitting element 200 and keep the electric power unchanged, which can avoid the reduction of the photoelectric efficiency of the light emitting element in the light emitting module due to the reduction of the input current of the display apparatus, and further affect the performance of the display apparatus.

The wiring layer 300 includes a first sub-wiring 301, a second sub-wiring 302, a third sub-wiring 303 and a fourth sub-wiring 304. The first sub-wiring 301 serves as a common wiring, the first electrodes in the first light-emitting element 201, the second light-emitting element 202 and the third light-emitting element 203 are connected to the first sub-wiring 301, and the second electrode in the first light-emitting element 201 is connected to the second sub-wiring 302.

In addition, in some embodiments, the number of light-emitting elements emitting different wavelengths in series may be the same or different. For example, the first light-emitting element 201 may include three light-emitting diodes in series, and the second light-emitting element 202 and the third light-emitting element may include two light-emitting diodes in series, which is not limited by the disclosure.

What is claimed is:

1. A display apparatus, comprising:
a thin-film transistor (TFT) substrate; and
a light-emitting module, arranged on the TFT substrate;
wherein the light-emitting module comprises a plurality of light-emitting elements, the plurality of light-emitting elements comprise a first light-emitting element emitting a first wavelength, a second light-emitting element emitting a second wavelength, and a third light-emitting element emitting a third wavelength; and a voltage of each of the plurality of light-emitting elements is greater than or equal to 3 volts (V) when a rated current is 1 microampere (μA).

2. The display apparatus as claimed in claim 1, wherein each of the plurality of light-emitting elements at least comprises two light-emitting diodes emitting a same wavelength and the two light-emitting diodes are connected in series; and each of the plurality of light-emitting elements further comprises a connection electrode, and the two light-emitting diodes emitting the same wavelength are connected in series on the light-emitting element through the connection electrode.

3. The display apparatus as claimed in claim 1, wherein each of the plurality of light-emitting elements at least comprises two light-emitting diodes emitting a same wavelength and the two light-emitting diodes are connected in series; and each of the plurality of light-emitting elements further comprises a tunneling junction, and the two light-emitting diodes emitting the same wavelength are connected in series on the light-emitting element through the tunneling junction.

4. The display apparatus as claimed in claim 2, wherein the light-emitting module further comprises a wiring layer, and the wiring layer is formed on the plurality of light-emitting elements and configured to electrically connect to the plurality of light-emitting elements, and the two light-emitting diodes emitting the same wavelength are connected in series through the wiring layer.

5. The display apparatus as claimed in claim 4, wherein the wiring layer comprises a connection part, and the two light-emitting diodes are connected in series through the connection part.

6. The display apparatus as claimed in claim 5, wherein the connection part comprises a first connection part, a second connection part, and a third connection part; the first light-emitting element comprises a first light-emitting diode and a second light-emitting diode emitting the first wavelength, the second light-emitting element comprises a third light-emitting diode and a fourth light-emitting diode emitting the second wavelength, and the third light-emitting element comprises a fifth light-emitting diode and a sixth light-emitting diode emitting the third wavelength; and
wherein the first light-emitting diode and the second light-emitting diode are connected in series through the first connection part, the third light-emitting diode and the fourth light-emitting diode are connected in series through the second connection part, and the fifth light-emitting diode and the sixth light-emitting diode are connected in series through the third connection part.

7. The display apparatus as claimed in claim 2, wherein a spacing between the two light-emitting diodes emitting the same wavelength is less than or equal to 50 micrometers (μm), and a spacing between light-emitting elements of the plurality of light-emitting elements emitting different wavelengths is less than or equal to 50 μm.

8. The display apparatus as claimed in claim 6, wherein the wiring layer comprises a first sub-wiring, a second sub-wiring, a third sub-wiring and a fourth sub-wiring; the first light-emitting diode, the third light-emitting diode and the fifth light-emitting diode are connected to the first sub-wiring, the second light-emitting diode is connected to the second sub-wiring, the fourth light-emitting diode is connected to the third sub-wiring, and the sixth light-emitting diode is connected to the fourth sub-wiring.

9. The display apparatus as claimed in claim 1, wherein the TFT substrate comprises a TFT driving circuit, and the TFT driving circuit is arranged to drive the light-emitting module in an active matrix manner.

10. The display apparatus as claimed in claim 1, wherein the light-emitting module further comprises a filling layer formed between adjacent light-emitting elements of the plurality of light-emitting elements, and a thickness of the filling layer is less than or equal to 15 μm.

11. The display apparatus as claimed in claim 10, wherein the light-emitting module further comprises an encapsulation layer and a conductive pad, the conductive pad is formed on the filling layer, the encapsulation layer is formed on a periphery of the conductive pad, and a thickness of the encapsulation layer is greater than 20 μm.

12. The display apparatus as claimed in claim 11, wherein a thickness of the conductive pad is greater than 20 μm.

13. The display apparatus as claimed in claim 1, wherein the light-emitting module further comprises a wiring layer formed on the plurality of light-emitting elements and a conductive pad formed on a side of the wiring layer facing away from the plurality of light-emitting elements; the wiring layer comprises a first sub-wiring, a second sub-wiring, a third sub-wiring, and a fourth sub-wiring; and the conductive pad comprises a first sub-pad, a second sub-pad, a third sub-pad, and a fourth sub-pad; and
wherein the first light-emitting element, the second light-emitting element and the third light-emitting element are connected to the first sub-pad through the first sub-wiring; the first light-emitting element is connected to the second sub-pad through the second sub-wiring; the second light-emitting element is connected to the third sub-pad through the third sub-wiring; and the third light-emitting element is connected to the fourth sub-pad through the fourth sub-wiring.

14. The display apparatus as claimed in claim 13, wherein the conductive pad comprises a conductive layer and a protective layer sequentially formed on the wiring layer, and the protective layer completely covers an upper surface of the conductive layer;
the conductive pad further comprises a eutectic layer, and the eutectic layer is located between the conductive layer and the protective layer; and
the eutectic layer is a single layer or a plurality of layers made of at least one material of tin (Sn), tin-silver (SnAg), and gold-tin (AuSn); and a thickness of the eutectic layer is in a range of 10-50 nanometers (nm).

15. The display apparatus as claimed in claim 1, wherein a spacing between the first light-emitting element and the third light-emitting element is D, a width of the light-emitting module in an arrangement direction of the light-emitting elements is P, and a value of D/P is less than or equal to 0.15.

16. The display apparatus as claimed in claim 1, wherein the light-emitting module further comprises:
a plurality of groups of light-emitting elements, arranged in a centrosymmetric manner, wherein each of the plurality of groups of light-emitting elements comprises the plurality of light-emitting elements;
a wiring layer, arranged in the centrosymmetric manner, formed on the plurality of groups of light-emitting elements and configured to electrically connect to the plurality of groups of light-emitting elements; and
a conductive pad, arranged in the centrosymmetric manner, formed on a side of the wiring layer facing away from the plurality of groups of light-emitting elements and electrically connected to the wiring layer.

17. The display apparatus as claimed in claim 16, wherein the wiring layer corresponding to each of the plurality of groups of light-emitting elements comprises a first sub-wiring, a second sub-wiring, a third sub-wiring, and a fourth sub-wiring; the conductive pad corresponding to each of the plurality of groups of light-emitting elements comprises a first sub-pad, a second sub-pad, a third sub-pad, and a fourth sub-pad; and
wherein the first light-emitting element, the second light-emitting element and the third light-emitting element are connected to the first sub-pad through the first sub-wiring; the first light-emitting element is connected to the second sub-pad through the second sub-wiring; the second light-emitting element is connected to the third sub-pad through the third sub-wiring; and the third light-emitting element is connected to the fourth sub-pad through the fourth sub-wiring.

18. The display apparatus as claimed in claim 16, wherein the conductive pad comprises 2 m+1 number of sub-pads, where m is a number of groups of light-emitting elements;
when the number of groups of light-emitting elements m=2, arrangement orders of the two groups of light-emitting elements are opposite;
the wiring layer includes a first wiring layer and a second wiring; the first wiring layer comprises a first sub-wiring, a second sub-wiring, a third sub-wiring, a fourth sub-wiring, and a fifth sub-wiring; and the second wiring layer comprises a sixth sub-wiring and a seventh sub-wiring; and the conductive pad comprises a first sub-pad, a second sub-pad, a third sub-pad, a fourth sub-pad and a fifth sub-pad;
the first light-emitting element, the second light-emitting element in a first group of the two groups of light-emitting elements and the third light-emitting element in a second group of the two groups of light-emitting elements are connected to the first sub-wiring; the third light-emitting element in the first group of the two groups of light-emitting elements is connected to the second sub-wiring; the third light-emitting element in the first group of the two groups of light-emitting elements and the first light-emitting element and the second light-emitting element in the second group of the two groups of light-emitting elements are connected to the third sub-wiring; the third light-emitting element in the second group of the two groups of light-emitting elements is connected to the fourth sub-wiring; the second light-emitting elements in the two groups of light-emitting elements are connected to the fifth sub-wiring; and the sixth sub-wiring and the seventh sub-wiring are respectively configured to connect to the first light-emitting elements in the two groups of light-emitting elements; and
the first sub-pad is electrically connected to the first sub-wiring; the second sub-pad is electrically connected to the second sub-wiring and the sixth sub-wiring; the third sub-pad is electrically connected to the third sub-wiring; the fourth sub-pad is electrically connected to the fourth sub-wiring and the seventh sub-wiring; and the fifth sub-pad is electrically connected to the fifth sub-wiring.

19. The display apparatus as claimed in claim 1, wherein the light-emitting module further comprises:
a plurality of groups of light-emitting elements, arranged in a centrosymmetric manner, each of the plurality of groups of light-emitting elements constitutes a pixel unit, and each of the plurality of groups of light-emitting elements comprises the plurality of light-emitting elements;
a wiring layer, arranged in the centrosymmetric manner, formed on the plurality of groups of light-emitting elements and configured to electrically connect to the plurality of groups of light-emitting elements; and
a conductive pad, arranged in the centrosymmetric manner, formed on a side of the wiring layer facing away from the light-emitting elements and electrically connected to the wiring layer; and
wherein the light-emitting module is capable of being overlapped with a layout of the light-emitting module before being rotated by 90 degrees in any direction.

20. The display apparatus as claimed in claim 19, wherein the light-emitting module comprises four groups of light-emitting elements, and the wiring layer corresponding to each of the four groups of light-emitting elements comprises a first sub-wiring, a second sub-wiring, a third sub-wiring, a fourth sub-wiring, a fifth sub-wiring, and a sixth sub-wiring; and
the conductive pad corresponding to each of the four groups of light-emitting elements comprises a common sub-pad, a first independent sub-pad, a second independent sub-pad and a third independent sub-pad; and
the first light-emitting element, the second light-emitting element and the third light-emitting element are respectively connected to the common sub-pad through the first sub-wiring, the second sub-wiring and the third sub-wiring; the first light-emitting element is connected to the first independent sub-pad through the fourth sub-wiring, the second light-emitting element is connected to the second independent sub-pad through the fifth sub-wiring, and the third light-emitting element is connected to the third independent sub-pad through the sixth sub-wiring.
